(19) United States
(12) Patent Application Publication
(10) Pub. No.: US 2017/0033012 A1
(43) Pub. Date: Feb. 2, 2017

(54) METHOD FOR FABRICATING FIN OF FINFET OF SEMICONDUCTOR DEVICE

(71) Applicant: TAIWAN SEMICONDUCTOR MANUFACTURING COMPANY LTD., HSINCHU (TW)

(72) Inventors: AMEY MAHADEV WALKE, HSINCHU (TW); HO-CHIEH HSIEH, HSINCHU CITY (TW); SANG HOO DHONG, HSINCHU CITY (TW)

(21) Appl. No.: 14/815,753

(22) Filed: Jul. 31, 2015

(51) Int. Cl. H01L 21/8234; H01L 21/311; H01L 21/762

(52) U.S. Cl. CPC H01L 21/823431; H01L 21/823481; H01L 21/76224; H01L 21/31144

(57) ABSTRACT

A method for fabricating a semiconductor device on a wafer includes: patterning a plurality of fins on the wafer; forming a shallow-trench isolation region to surround the plurality of fins; and etching the STI region to form the plurality of fins having a fin height such that the semiconductor device has a desired power consumption. The plurality of fins corresponds to a plurality of finFETs of the semiconductor device respectively.

### BACKGROUND

The present invention relates to a method for fabricating a semiconductor device and, more particularly, to a method for trimming a power consumption of a semiconductor device according to a fin height of a finFET.

The dominant semiconductor technology used for the manufacture of ultra-large scale integrated (ULSI) circuits is planar metal-oxide-semiconductor field effect transistor (MOSFET) technology. To save power, the gate length and width of the planar transistor are scaled down. As the gate length of the planar transistor is reduced, the planar transistor may suffer a problem that the gate cannot substantially control the on/off states of the channel. Phenomena resulting in reduced gate control due to transistors having short channel lengths are termed short-channel effects. Moreover, scaling the width of a planar transistor also affects the threshold voltage of the transistor, which is called as narrow width effects. Accordingly, fin field-effect transistors (finFETs) are developed to alleviate the above problems, e.g. the narrow and short channel effects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a perspective view of a finFET in accordance with some embodiments.

FIG. 2 is a flowchart illustrating a method for fabricating a semiconductor device on a wafer in accordance with some embodiments.

FIG. 3 is a cross-sectional view of a plurality of fins on a wafer in accordance with some embodiments.

FIG. 4 is a cross-sectional view of a plurality of fins and an STI region on a wafer in accordance with some embodiments.

FIG. 5 is a cross-sectional view of a plurality of fins, an STI region, and a mask on a wafer in accordance with some embodiments.

FIG. 6 is a cross-sectional view of a plurality of exposed fins on a wafer in accordance with some embodiments.

FIG. 7 is a cross-sectional view of the exposed fins and a plurality of gate stacks on a wafer in accordance with some embodiments.

FIG. 8 is a flowchart illustrating a method for fabricating a semiconductor device on a wafer in accordance with some embodiments.

FIG. 9 is a cross-sectional view of a fin on a wafer in accordance with some embodiments.

FIG. 10 is a cross-sectional view of a fin and an STI region on a wafer in accordance with some embodiments.

FIG. 11 is a cross-sectional view of a fin, an STI region, and a mask on a wafer in accordance with some embodiments.

FIG. 12 is a cross-sectional view of an exposed fin on a wafer in accordance with some embodiments.

FIG. 13 is a cross-sectional view of an exposed fin and a gate stack on a wafer in accordance with some embodiments.

FIG. 14 is a flowchart illustrating a method for fabricating a semiconductor device on a wafer in accordance with some embodiments.

FIG. 15 is a cross-sectional view of a plurality of fins on a wafer in accordance with some embodiments.

FIG. 16 is a cross-sectional view of a plurality of fins and a plurality of STI regions on a wafer in accordance with some embodiments.

FIG. 17 is a cross-sectional view of a plurality of fins, a plurality of STI regions, and a plurality of masks on a wafer in accordance with some embodiments.

FIG. 18 is a cross-sectional view of a plurality of exposed fins on a wafer in accordance with some embodiments.

FIG. 19 is a cross-sectional view of a plurality of exposed fins and a plurality of gate stacks on a wafer in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The making and using of the embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Further, spatially relative terms, such as “beneath,” “below,” “lower,” “above,” “upper”, “lower”, “left”, “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It will be understood that when an element is referred to as being “connected to” or “coupled to” another element, it may be directly connected to or coupled to the other element, or intervening elements may be present.

In the present disclosure, an effective way of implementing a power trim of finFETs is proposed. The power trim is suitable for tailoring the power consumption and/or performance of a chip without changing the mask set used for fabricating the chip during the semiconductor fabricating process. The power trim of the finFETs is carried out by adjusting the fin height of the finFETs globally or locally without changing the channel length of the finFETs. When the fin heights of all finFETs on a wafer are scaled by the same magnitude, the adjustment is called a global adjustment. When the fin heights of a portion of finFETs on a wafer are scaled by a magnitude, and the fin heights of another portion of finFETs on the wafer are scaled by another magnitude, the adjustment is called a local adjustment.

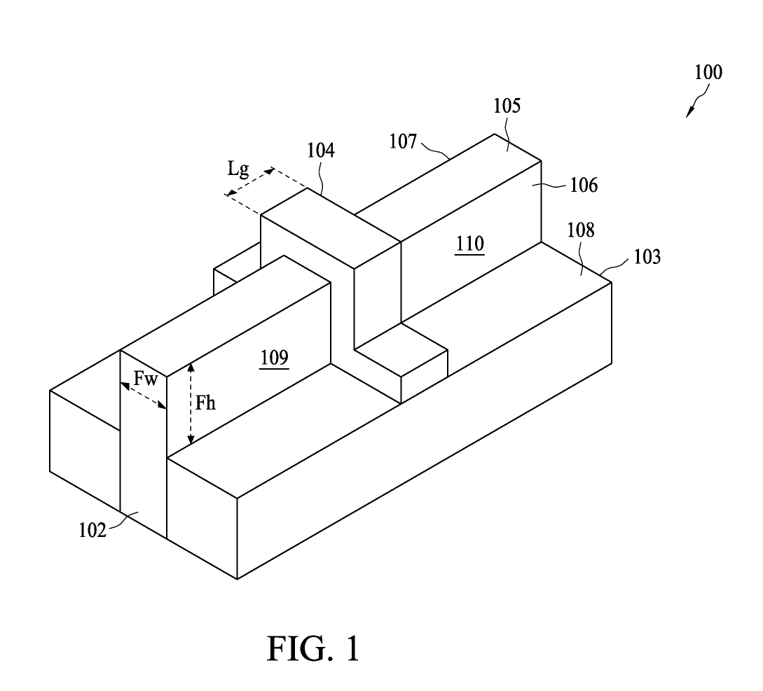

FIG. 1 is a diagram illustrating a perspective view of a finFET 100 in accordance with some embodiments. The finFET 100 comprises a fin 102 and a gate stack 104. An STI (Shallow-trench isolation) region 103 is formed to surround a lower portion of the fin 102, while an upper portion of the fin 102 is exposed from the STI region 103. The gate stack 104 is formed over a portion of a top surface 105, a portion of sidewalls 106, 107 of the fin 102, and a portion of a top surface 108 of the STI region 103. The gate stack 104 may comprise a gate dielectric and a gate electrode. The gate dielectric is formed over the portion of the top surface 105, the portion of sidewalls 106, 107 of the fin 102, and the portion of a top surface 108 of the STI region 103. The gate electrode is formed over the gate dielectric for conducting a voltage signal to the gate dielectric in order to turn on the finFET 100. The gate dielectric can be a combination of one or more insulating materials. The gate electrode can be a combination of one or more metals and/or semiconductor materials. The gate stack 104, or more specifically the gate dielectric, has a gate length Lg, which is also called a channel length. The fin 102 has a fin width Fw. A fin height Fh is the length from the top surface 108 of the STI region 103 to the top surface 105 of the fin 102. The drain region 109 and the source region 110 of the finFET 100 are the portions of the fin 102 extending from two sides of the gate stack 104. The drain region 109 and the source region 110 are lightly doped by implanting the fin 102. It is noted that the finFET 100 is just a simplified illustration used for discussing the inventive features of the present disclosure. One of ordinary skill in the art will realize that other functional layers are also included.

The effective or total width Wf of the finFET 100 is a total length of the fin width Fw and two times the fin height Fh, as expressed in the following equation (1):

Wf=Fw+2*Fh (1).

Accordingly, the effective width Wf of the finFET 100 can be tuned by changing the fin height Fh of the fin 102 while keeping the fin width Fw unchanged. A taller fin height will cause the finFET 100 to generate a higher current density. However, a taller fin height will also cause a higher gate capacitance, which results in a higher power consumption of the finFET 100. In application, the semiconductor device implemented by finFETs having a short fin height is used for ultra-low power (ULP) applications whereas the semiconductor device implemented by finFETs having a tall fin height is used for high performance or high power applications. Accordingly, there is an additional power tuning knob as adjustment of the fin height of the finFETs in a semiconductor device in designing the semiconductor device. The semiconductor device may be a single chip.

Specifically, for a semiconductor device such as a digital circuit, the active power consumption Pa is the power consumption of the digital circuit during operation. The active power consumption Pa is proportional to the net capacitance C, the power supply V and the operation frequency f of the digital circuit, as denoted in the following relation (2):

Pa∝CV²f (2).

The operation frequency f can be regarded as the speed of the digital circuit. According to equation (2), when the net capacitance C decreases, the active power consumption Pa also decreases.

Moreover, the operation frequency f of the digital circuit is proportional to the driven current I of the digital circuit, and the operation frequency f is inversely proportional to the net capacitance C and the power supply V, as denoted in the following relation (3):

$$f ∝ \frac{I}{CV} \qquad ( 3 )$$

When the net capacitance C decreases, the operation frequency f increases.

The net capacitance C can be regarded as a sum of the gate capacitance of the finFETs Cg and the parasitic load capacitance Cp in the digital circuit, as expressed in the following equation (4):

C=Cg+Cp (4)

The gate capacitance Cg of a finFET is proportional to the gate length Lg and the effective width Wf of the finFET, as denoted in the following relation (5):

Cg∝Wf*Lg*Cox (5)

Cox represents the oxide capacitance per unit area of the gate of the finFET. According to the equation (1), the effective width Wf is proportional to the fin height Fh of the fin of the finFET. Therefore, when the fin height Fh of the finFET decreases, the effective width Wf also decreases. Then, the gate capacitance Cg also decreases.

Moreover, for a single finFET, the driven current Id of the finFET is proportional to the effective width Wf of the finFET, as denoted in the following relation (6):

Id∝Wf (6)

When the fin height Fh of the finFET is scaled, the driven current Id and the gate capacitance Cg of the finFET are also scaled by the same magnitude.

Accordingly, for the digital circuit, when the fin heights Fh of the finFETs in the digital circuit are reduced, the active power consumption Pa of the digital circuit is also reduced. However, the operation frequency f of the digital circuit may be kept intact or may just be slightly deviated. This is because the operation frequency f of the digital circuit is proportional to the driven current I and is inversely proportional to the net capacitance C as illustrated in the relation (3). Therefore, when the fin heights Fh of the finFETs in the digital circuit are reduced, the active power consumption Pa of the digital circuit is reduced while the performance of the digital circuit need not be greatly affected.

According to the equations or relations (1)˜(6), when a semiconductor device, which is to be implemented by finFET technology, having a specific function or performance is designed, the semiconductor device can be fabricated to have finFETs with any desired length in order to trim or set the power consumption of the semiconductor device. For example, when the semiconductor device is applied in a server or desktop, the semiconductor device can be fabricated to have the tall fin finFETs in order to have high power consumption. For another example, when the semiconductor device is applied in ultra-low power (ULP) or Internet of Things (IoT) applications, the semiconductor device can be fabricated to have the short fin finFETs in order to have low power consumption. For another example, when the semiconductor device is applied in normal applications (e.g. a mobile device), the semiconductor device can be fabricated to have the normal fin finFETs in order to have normal power consumption. Accordingly, the fin height of the finFETs in a semiconductor device can be used as an effective knob to tune the power consumption of the semiconductor device to fit the different applications.

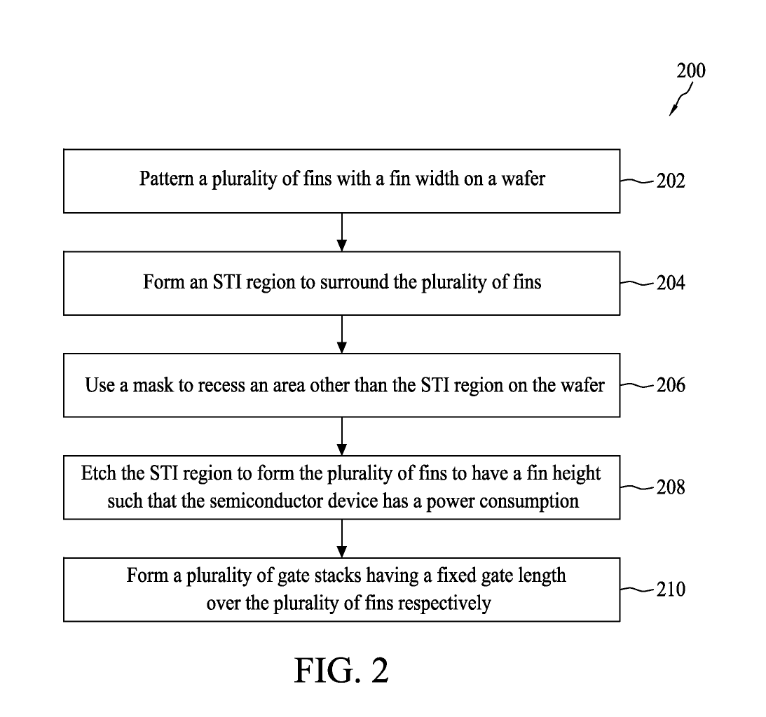

FIG. 2 is a flowchart illustrating a method 200 for fabricating a semiconductor device on a wafer in accordance with some embodiments. The semiconductor device is designed with a specific function or an operating frequency. The method 200 is applied for fabricating the semiconductor device so that the semiconductor has a desired power consumption that conforms to a power requirement for application. Specifically, when a semiconductor manufacturer, such as an IC foundry, receives a design layout of the semiconductor device, the semiconductor manufacturer may perform the method 200 to define the desired power consumption in the semiconductor device. The design layout of the semiconductor device may be compiled into a GDS (Graphic Data System) file or GDSII file. The method 200 at least comprises an operation 202 for patterning a plurality of fins with a fin width Fw on a wafer, an operation 204 for forming an STI region to surround the plurality of fins, an operation 206 for using a mask to recess an area other than the STI region on the wafer, an operation 208 for etching the STI region to form a plurality of fins that have a fin height such that the semiconductor device has the desired power consumption, and an operation 210 for forming a plurality of gate stacks having a fixed gate length over the plurality of fins respectively. It should be noted that the method 200 is a simplified method for the sake of illustrative purposes. Provided that substantially the same result is achieved, the operations of the flowchart shown in FIG. 2 need not be performed in the exact order or continuously so that other operations can be inserted.

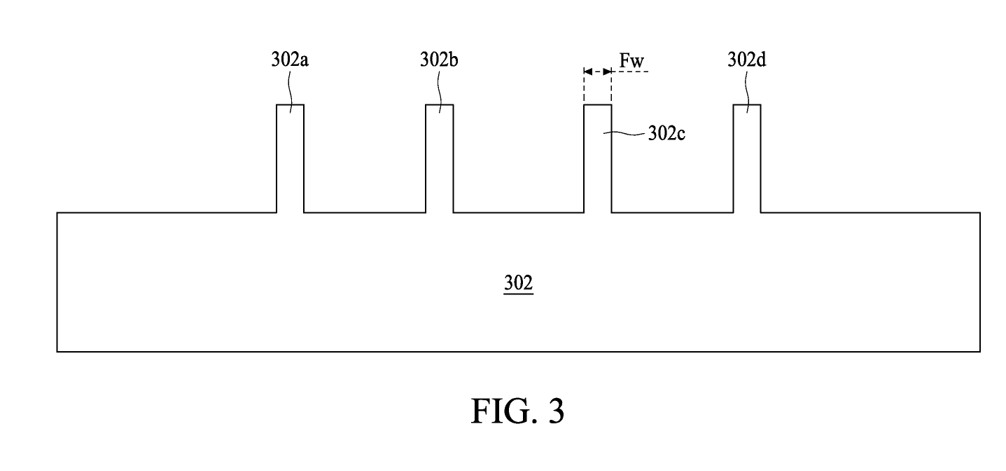

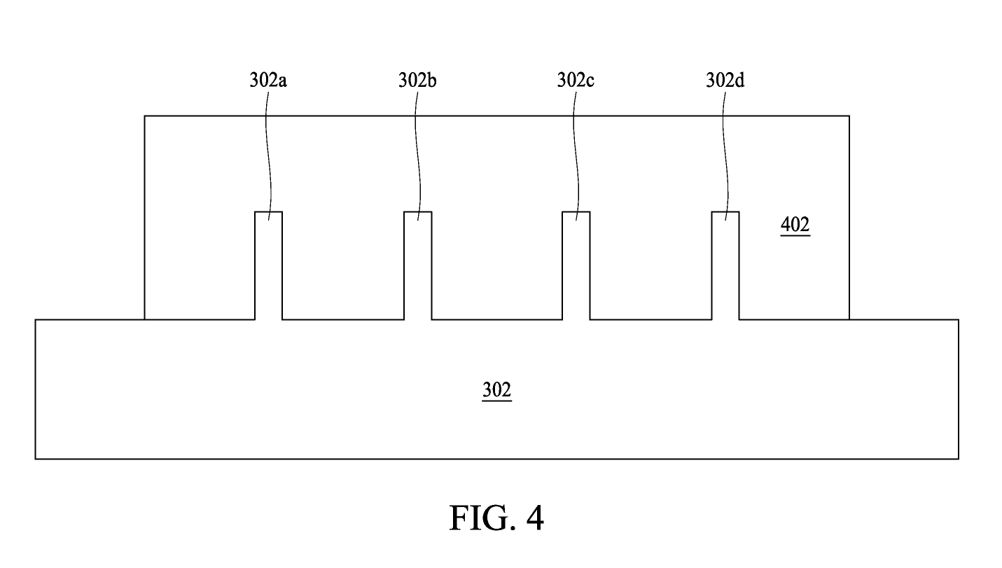

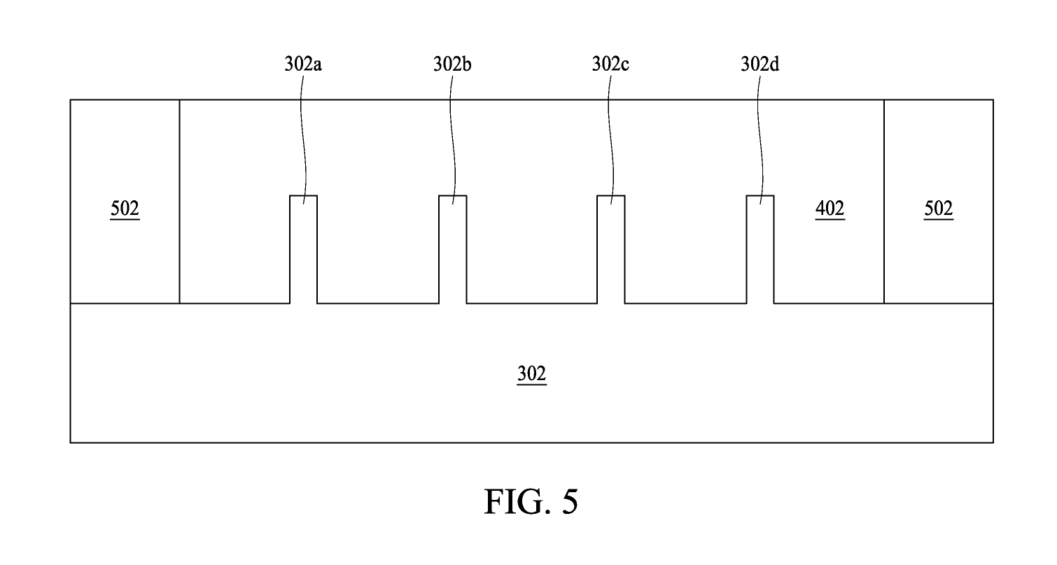

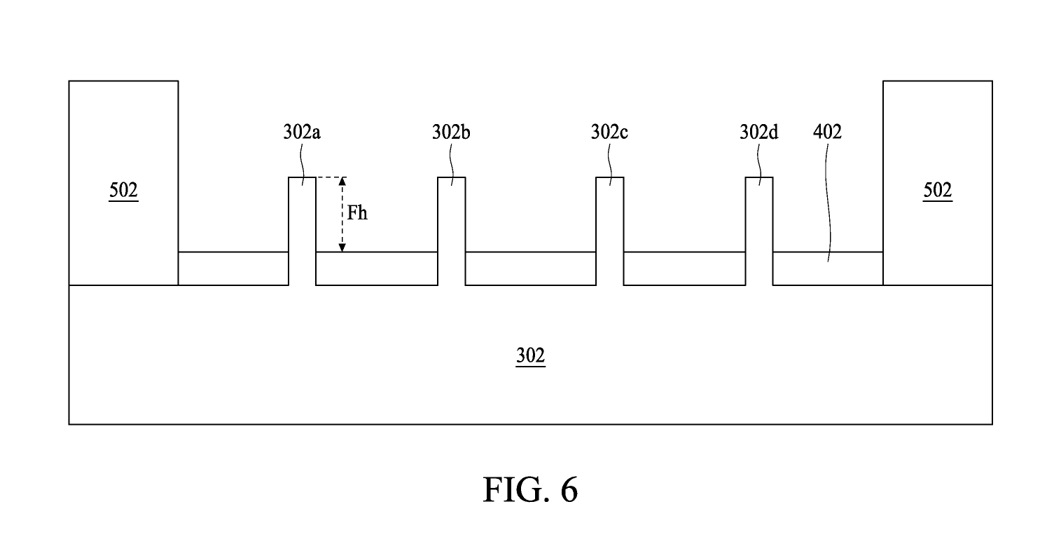

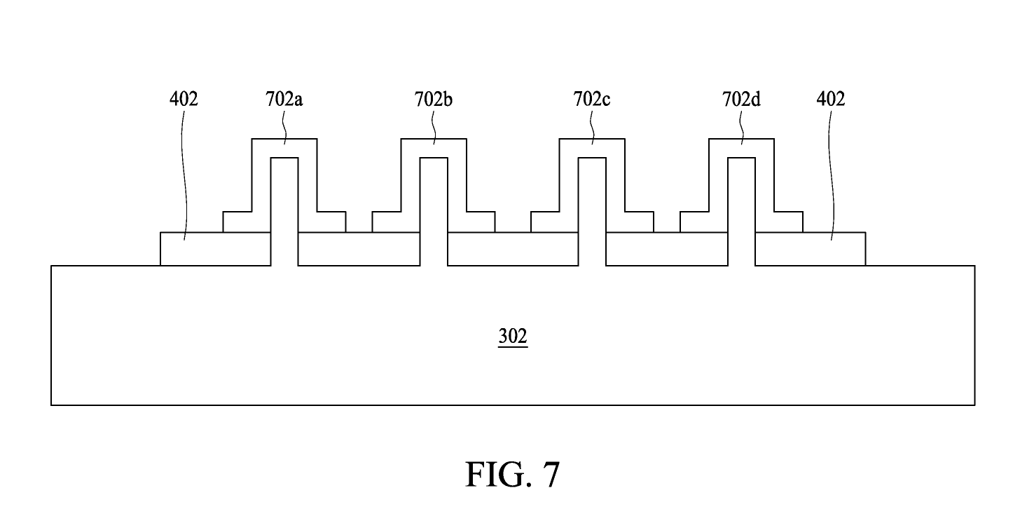

FIGS. 3-7 are diagrams illustrating stages in the fabrication of the semiconductor device in accordance with some embodiments. Specifically, FIG. 3 is a cross-sectional view of a plurality of fins 302a-302d on a wafer 302 in accordance with some embodiments. FIG. 4 is a cross-sectional view of the fins 302a-302d and an STI region 402 on the wafer 302 in accordance with some embodiments. FIG. 5 is a cross-sectional view of the fins 302a-302d, the STI region 402, and a mask 502 on the wafer 302 in accordance with some embodiments. FIG. 6 is a cross-sectional view of the exposed fins 302a-302d on the wafer 302 in accordance with some embodiments. FIG. 7 is a cross-sectional view of the exposed fins 302a-302d and a plurality of gate stacks 702a-702d on the wafer 302 in accordance with some embodiments.

Referring to FIG. 3 and the operation 202, the substrate of the wafer 302 is etched to form a plurality of trenches such that the fins 302a-302d are formed on the wafer 302. In this embodiment, the fins 302a-302d represent all the fins on the wafer 302.

Referring to FIG. 4 and the operation 204, the STI region 402 is formed in the trenches to surround and cover the fins 302a-302d. The STI region 402 may be an oxide layer formed by a high density plasma chemical vapor deposition process (HDP-CVD).

Referring to FIG. 5 and the operation 206, the mask 502 is formed to recess an area other than the STI region 402 on the wafer 302. Therefore, the STI region 402 is not masked by the mask 502.

Referring to FIG. 6 and the operation 208, the STI 402 is etched to expose the fins 302a-302d until the fin height Fh reaches a specific length. The specific length depends on the power consumption of the semiconductor device as previously discussed. For example, when the fin height Fh is higher than about 45 nanometer (nm), the power consumption of the fabricated semiconductor device can be regarded as high power consumption. When the fin height Fh is in a range of about 30˜45 nm, the power consumption can be regarded as normal power consumption. When the fin height Fh is smaller than about 30 nm, the power consumption can be regarded as low power consumption. It should be noted that the above category is simply an example and is not a limitation of the present embodiments.

For another example, according to the equation (1), when the effective width Wf of each fin in the exposed fins 302a-302d is higher than about 95 nm, the power consumption of the fabricated semiconductor device can be regarded as high power consumption. When the effective width Wf of each fin in the fins 302a-302d is in a range of about 75˜95 nm, the power consumption is normal power consumption. When the effective width Wf of each fin in the fins 302a-302d is smaller than about 75 nm, the power consumption is low power consumption.

Referring to FIG. 7 and the operation 210, when a desired fin height Fh is obtained, the gate stacks 702a-702d having a fixed gate length (i.e. Lg) are formed over the fins 302a-302d, respectively. In operation 210, the mask 502 formed in operation 206 is also removed. It is noted that the operations 202-210 merely illustrate the formation of the fins 302a-302d of a plurality of finFETs in the semiconductor device. Other operations may be applied to form the remaining components of the semiconductor device, and the detailed description is omitted here for brevity.

When all of the finFETs on a wafer are trimmed by the same magnitude, no additional mask is required during the semiconductor manufacturing process. This is because the fin heights of the fins on the wafer depend on the depth of the etching process performed upon the STI region 402 when the mask set assigned for the wafer is designed. Accordingly, for a semiconductor device with a mask set, a semiconductor manufacturer can use the same mask set to fabricate or trim the semiconductor device in order to perform different applications respectively by adjusting the fin heights of the fins on the wafer.

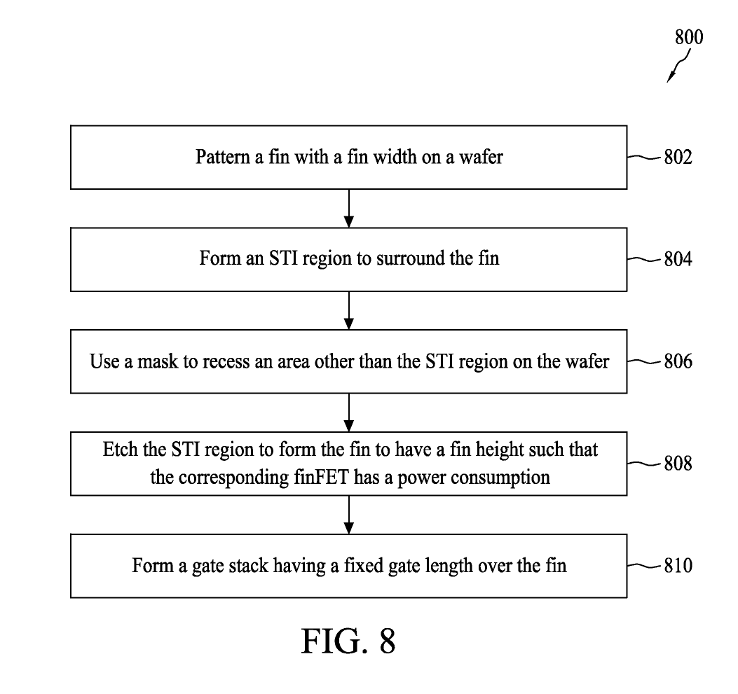

According to the method 200, all finFETs on the wafer 302 are adjusted to have the same fin height such that the semiconductor device has the specific power consumption. Therefore, the adjustment performed by the method 200 can be regarded as the global adjustment of the finFETs of the semiconductor device. However, this is not a limitation of the present disclosure. The adjustment may also be applied to adjust the fin height of a portion of finFET(s) instead of all finFETs on a wafer for adjusting the power consumption of the portion of finFET(s) of a semiconductor device on the wafer. FIG. 8 is a flowchart illustrating a method 800 for fabricating a semiconductor device on a wafer in accordance with some embodiments. Specifically, when a semiconductor manufacturer receives a design layout of a semiconductor device, the method 800 is applied to adjust the fin height of one finFET, for example, in the semiconductor device in order to adjust power consumption of the finFET. The design layout of the semiconductor device may be compiled into a GDS file or GDSII file. The method 800 at least comprises an operation 802 for patterning a fin with a fin width Fw′ on the wafer, an operation 804 for forming an STI region to surround the fin, an operation 806 for using a mask to recess an area other than the STI region on the wafer, an operation 808 for etching the STI region to form the fin having a fin height such that the corresponding finFET has a desired power consumption, and an operation 810 for forming a gate stack having a fixed gate length over the fin. It should be noted that the method 800 is a simplified method for the sake of illustrative purposes. Provided that substantially the same result is achieved, the operations of the flowchart shown in FIG. 8 need not be performed in the exact order or continuously so that other operations can be inserted.

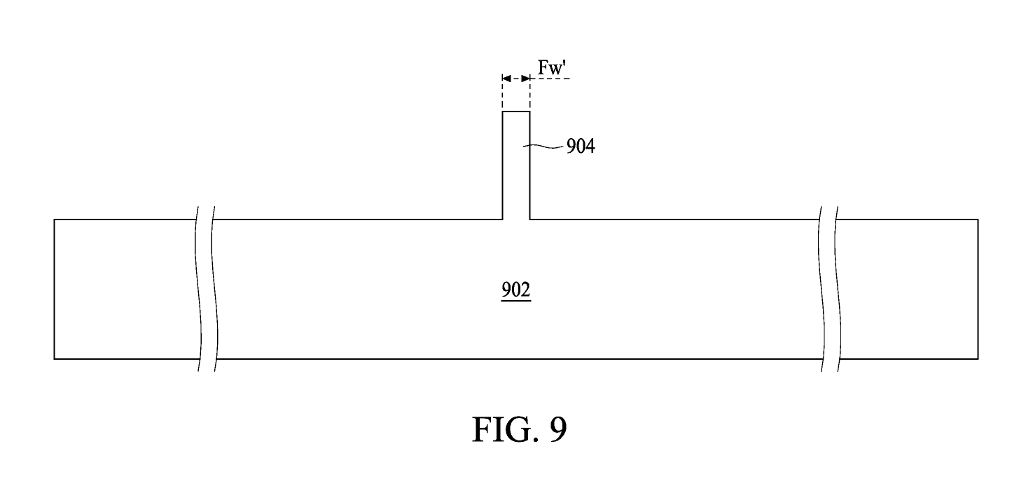

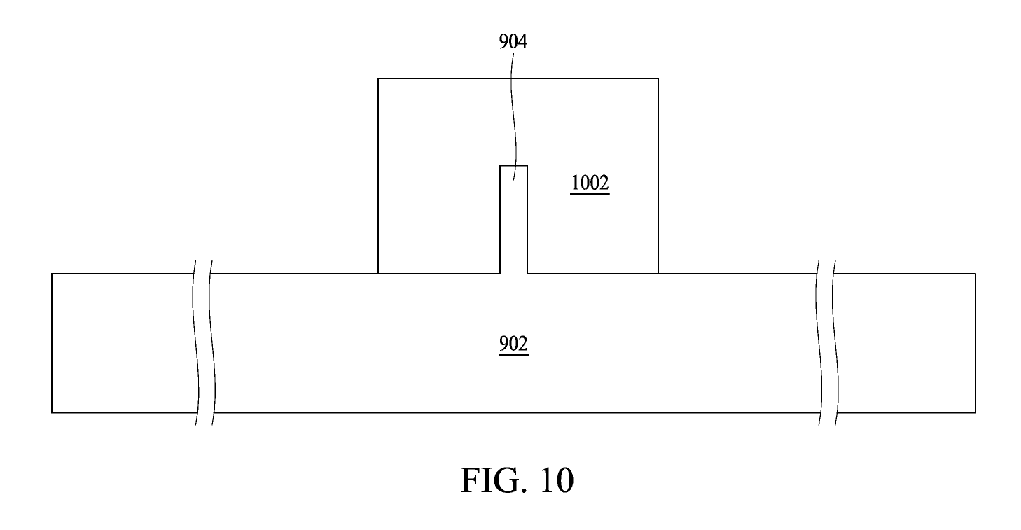

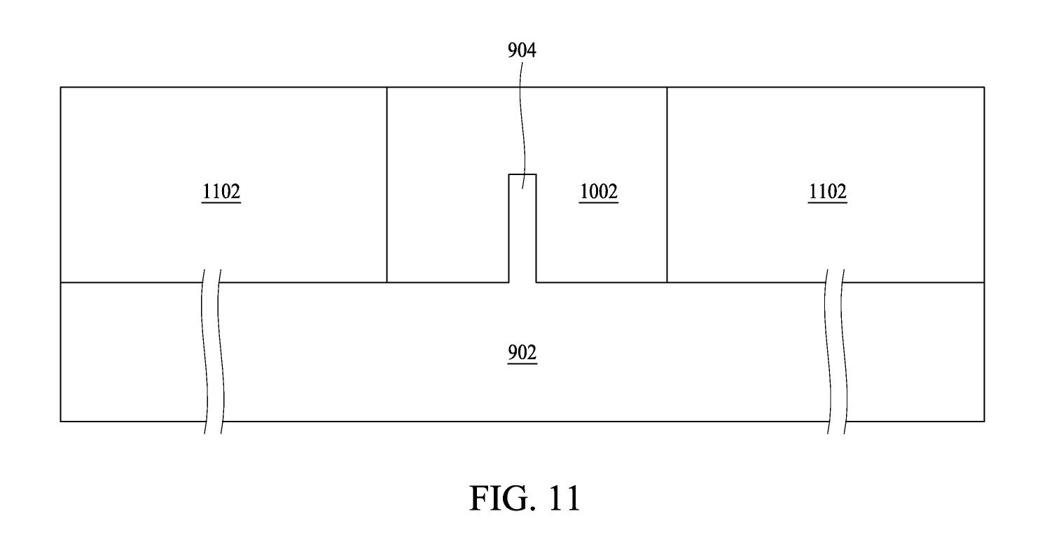

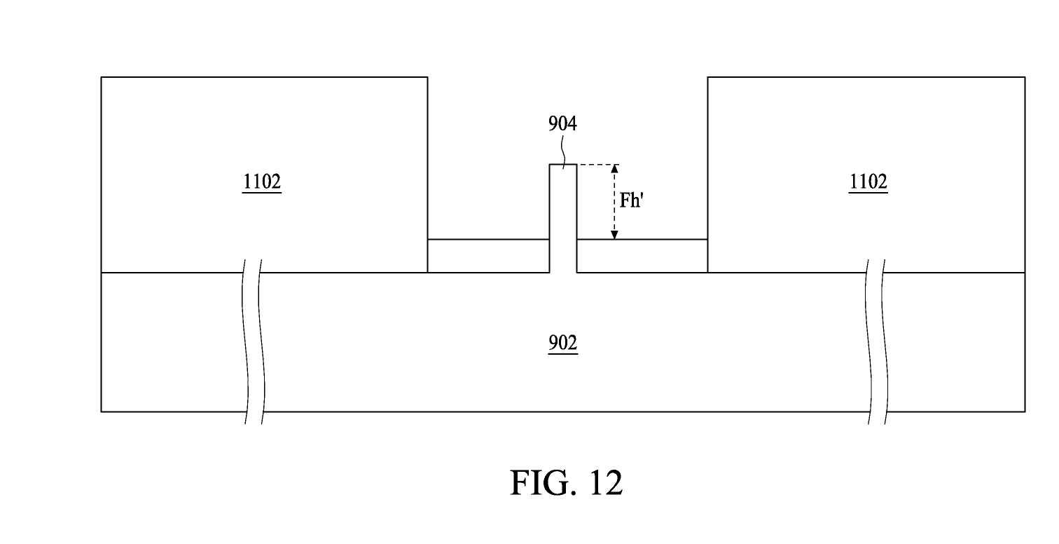

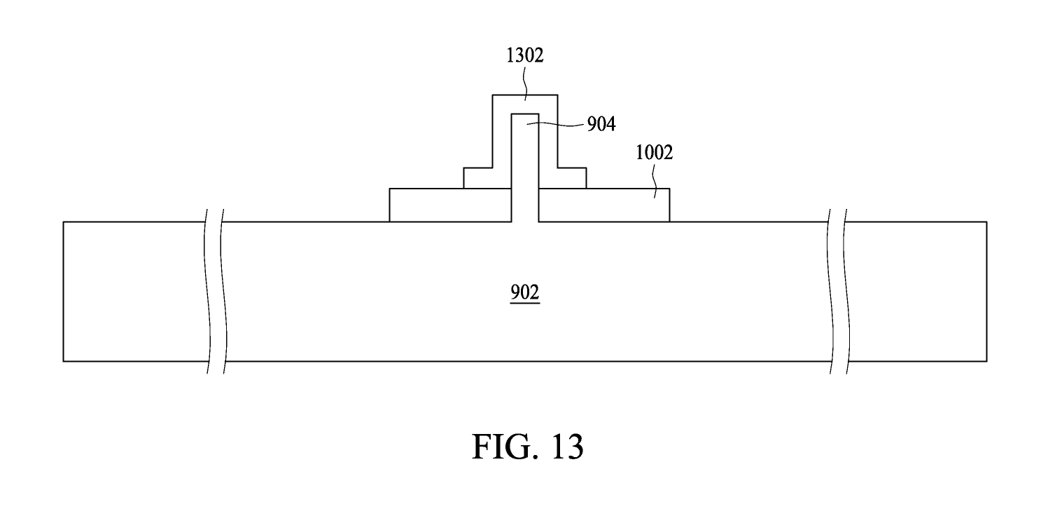

FIGS. 9-13 are diagrams illustrating stages in the fabrication of the semiconductor device in accordance with some embodiments. Specifically, FIG. 9 is a cross-sectional view of a fin 904 with a fin width Fw′ on a wafer 902 in accordance with some embodiments. FIG. 10 is a cross-sectional view of the fin 904 and an STI region 1002 on the wafer 902 in accordance with some embodiments. FIG. 11 is a cross-sectional view of the fin 904, the STI region 1002, and a mask 1102 on the wafer 902 in accordance with some embodiments. FIG. 12 is a cross-sectional view of the exposed fin 904 on the wafer 902 in accordance with some embodiments. FIG. 13 is a cross-sectional view of the exposed fin 904 and a gate stack 1302 on the wafer 902 in accordance with some embodiments.

Referring to FIG. 9 and the operation 802, the substrate of the wafer 902 is etched to form the fin 904 on the wafer 902. Only one fin is shown in FIGS. 9-13 for illustrative purposes. The fin 904 may be replaced by other number but not all of the fins on the wafer 902.

Referring to FIG. 10 and the operation 804, the STI region 1002 is formed to surround and cover the fin 904. The STI region 1002 may be an oxide layer formed by a high density plasma chemical vapor deposition process (HDP-CVD).

Referring to FIG. 11 and the operation 806, the mask 1102 is used to recess an area other than the STI region 1002 on the wafer 902. Therefore, the STI region 1002 is not masked by the mask 1102.

Referring to FIG. 12 and the operation 808, the STI 1002 is etched to expose the fin 904 until the fin height Fh′ reaches a specific length. The specific length depends on the power consumption of the finFET, as explained in the above paragraphs.

Referring to FIG. 13 and the operation 812, when the fin height Fh′ is obtained, the gate stack 1302 having a fixed gate length (i.e. Lg′) is formed over the fin 904. In operation 810, the mask 1102 formed in the operation 806 is removed. It is noted that the operations 802-810 merely illustrate the formation of the fin 904 in the semiconductor device. Other operations may be applied to form the remaining components of the semiconductor device, and the detailed description is omitted here for brevity.

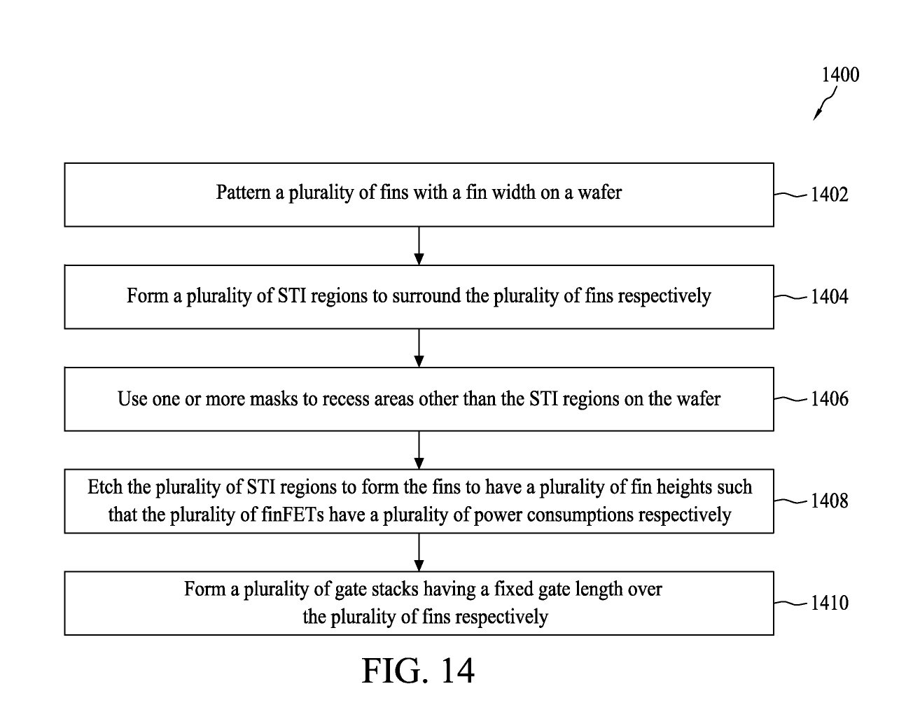

According to the method 800, only a predetermined number of finFETs on the wafer 902 are trimmed or adjusted so that these finFETs have the same fin height and hence a specific power consumption. Therefore, the adjustment performed by the method 800 can be regarded as the local adjustment of the finFETs on the wafer 902. However, this is not a limitation of the local adjustment of the present disclosure. Another local adjustment may be the case of adjusting a plurality of fin heights of a plurality of finFETs on a wafer to make the plurality of finFETs have a plurality of power consumptions, when a semiconductor manufacturer receives a design layout of the semiconductor device. FIG. 14 is a flowchart illustrating a method 1400 for fabricating a semiconductor device on a wafer in accordance with some embodiments. The design layout of the semiconductor device may be compiled into a GDS file or GDSII file. The method 1400 at least comprises an operation 1402 for patterning a plurality of fins with a fin width Fw″ on the wafer, an operation 1404 for forming a plurality of STI regions to surround the plurality of fins, respectively, an operation 1406 for using one or more masks to recess areas other than the STI regions on the wafer, an operation 1408 for etching the plurality of STI regions to form the fins having a plurality of fin heights such that the plurality of finFETs have a plurality of power consumptions, and an operation 1410 for forming a plurality of gate stacks having a fixed gate length over the plurality of fins. It should be noted that the method 1400 is a simplified method for the sake of illustrative purposes. Provided that substantially the same result is achieved, the operations of the flowchart shown in FIG. 14 need not be performed in the exact order or continuously so that other operations can be inserted.

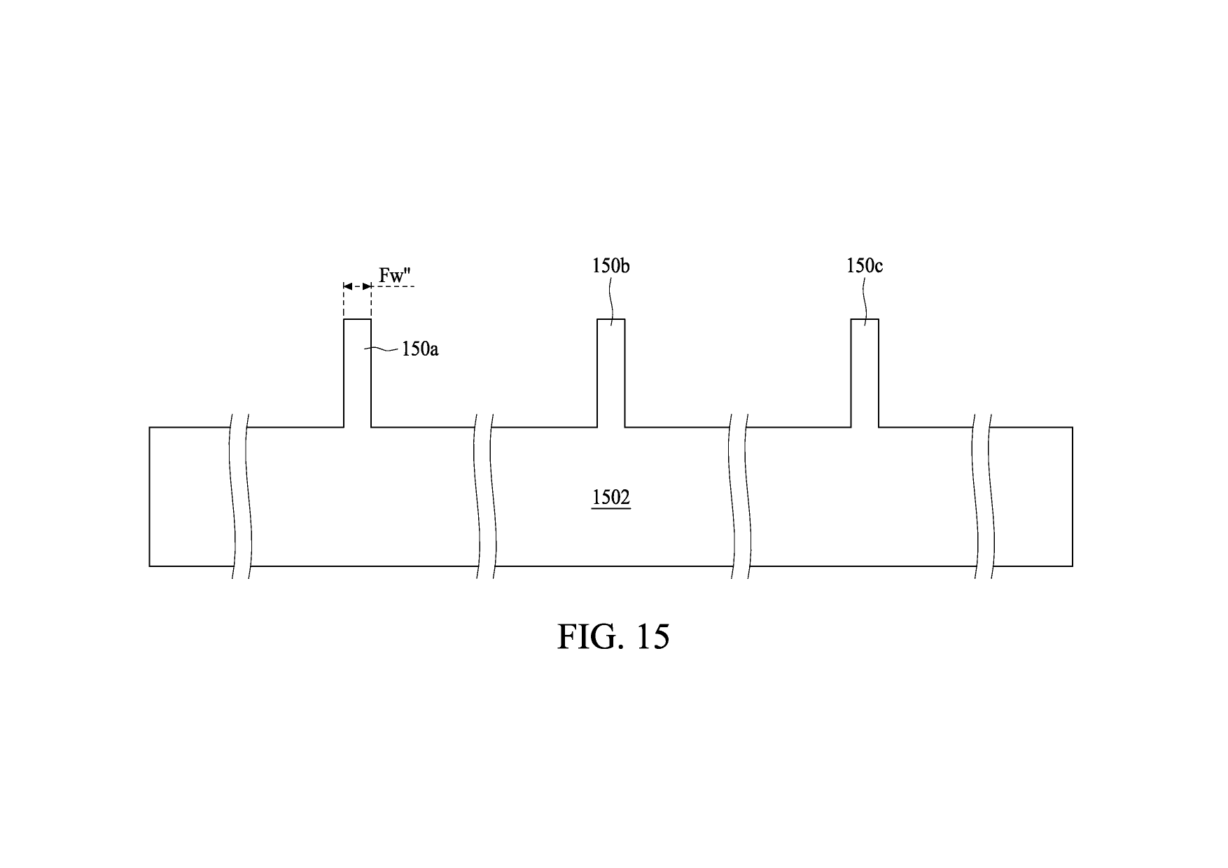

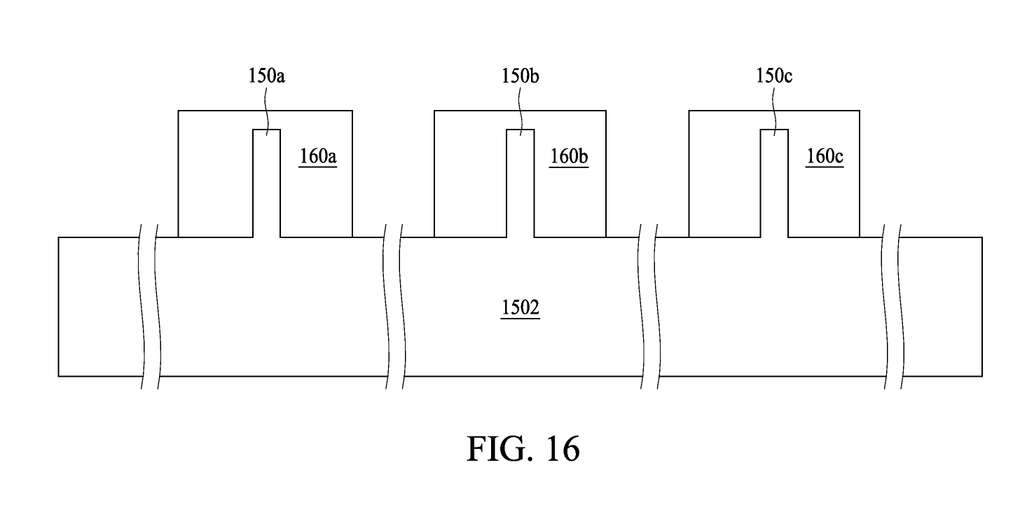

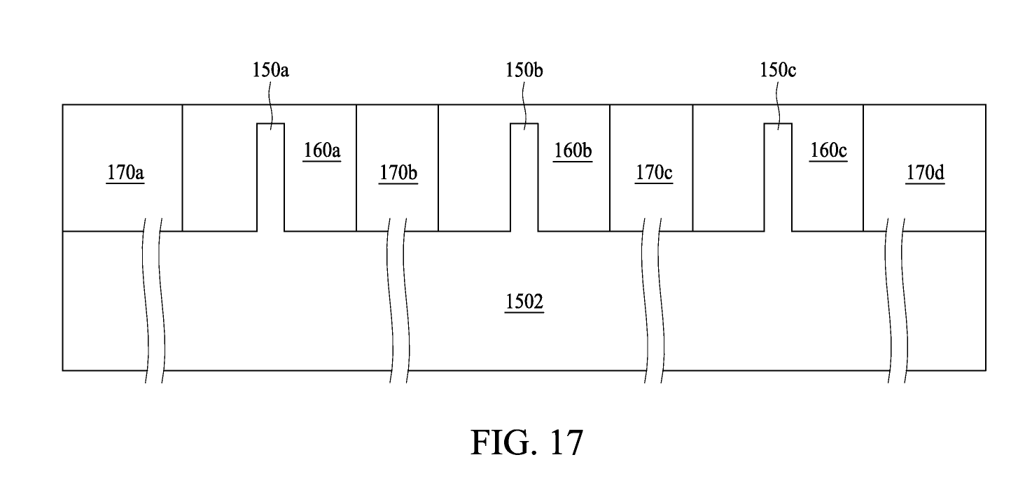

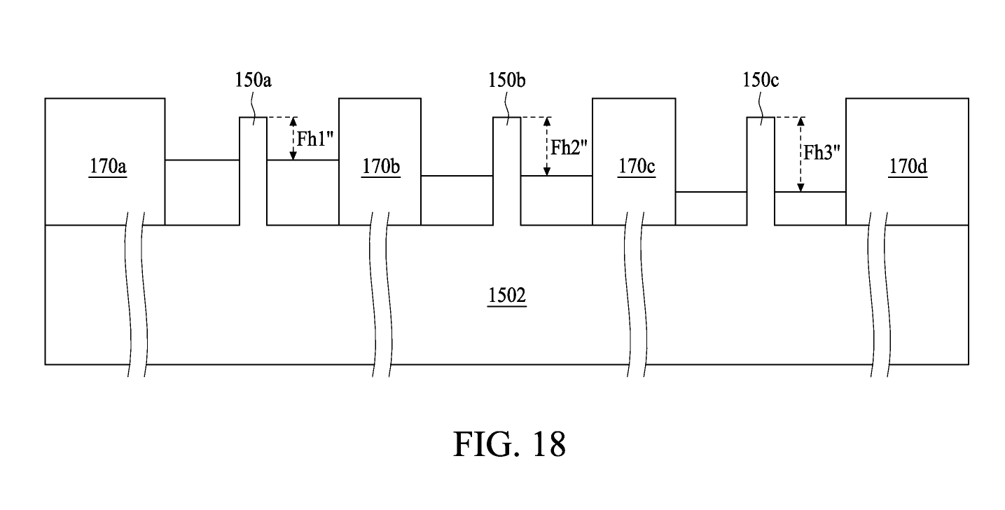

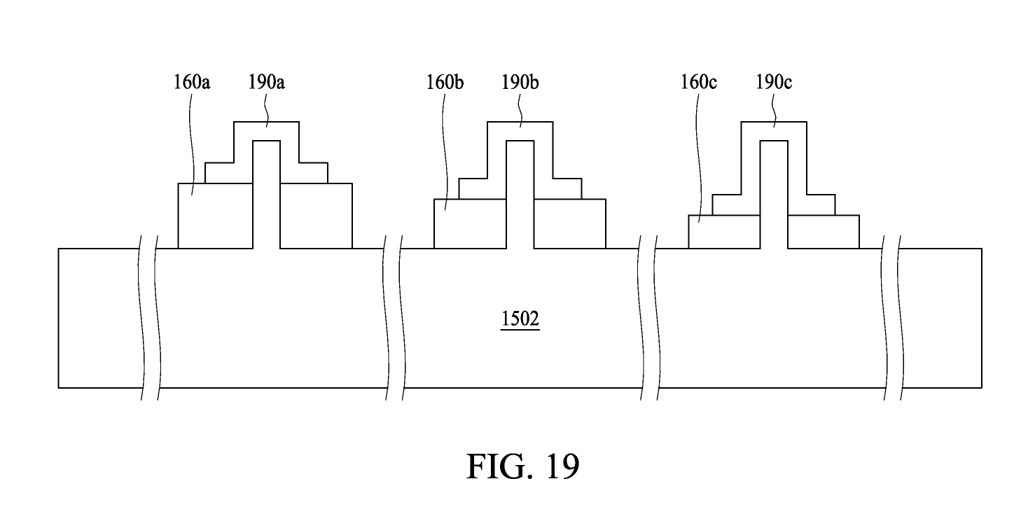

FIGS. 15-18 are diagrams illustrating stages in the fabrication of the semiconductor device in accordance with some embodiments. Specifically, FIG. 15 is a cross-sectional view of a plurality of fins 150a, 150b and 150c on a wafer 1502 in accordance with some embodiments. FIG. 16 is a cross-sectional view of the fins 150a, 150b and 150c and a plurality of STI regions 160a, 160b and 160c on the wafer 1502 in accordance with some embodiments. FIG. 17 is a cross-sectional view of the fins 150a, 150b and 150c, the STI regions 160a, 160b and 160c, and a plurality of masks 170a, 170b, 170c and 170d on the wafer 1502 in accordance with some embodiments. FIG. 18 is a cross-sectional view of the exposed fins 150a, 150b and 150c on the wafer 1502 in accordance with some embodiments. FIG. 19 is a cross-sectional view of the exposed fins 150a, 150b and 150c and a plurality of gate stacks 190a, 190b and 190c on the wafer 1502 in accordance with some embodiments.

Referring to FIG. 15 and the operation 1402, the substrate of the wafer 1502 is etched to form the fins 150a, 150b and 150c on the wafer 1502.

Referring to FIG. 16 and the operation 1404, the STI regions 160a, 160b and 160c are disposed to surround and cover the fins 150a, 150b and 150c, respectively. The STI regions 160a, 160b and 160c may be an oxide layer formed by a high density plasma chemical vapor deposition process (HDP-CVD).

Referring to FIG. 17 and the operation 1406, the masks 170a, 170b, 170c and 170d are used to recess the areas other than the STI regions 160a, 160b and 160c on the wafer 1502.

Referring to FIG. 18 and the operation 1408, the STI regions 160a, 160b and 160c are etched to expose the fins 150a, 150b and 150c such that the fins 150a, 150b and 150c have a plurality of fin heights Fh1″, Fh2″ and Fh3″, respectively. The fin heights Fh1″, Fh2″ and Fh3″ may have different lengths, which depend on the required power consumptions of the fabricated finFETs, as explained in the above paragraphs. It is noted that the fins 150a, 150b and 150c may be formed by different etching processes in the operation 1408. For example, the shortest fin of the fins 150a, 150b and 150c may be firstly formed by etching the corresponding STI region (e.g. 160a), and the longest fin may be lastly formed by etching the corresponding STI region (e.g. 160c).

Referring to FIG. 19 and the operation 1410, when the fin heights Fh1″, Fh2″ and Fh3″ are obtained, the gate stacks 190a, 190b and 190c having a fixed gate length are formed over the fins 150a, 150b and 150c, respectively. In operation 1410, the masks 170a, 170b, 170c and 170d formed in operation 1406 are removed. It is noted that the operations 1402-1410 merely illustrate the formation of the fins 150a, 150b and 150c in the semiconductor device. Other operations may be applied to form the remaining components of the semiconductor device, and the detailed description is omitted here for brevity.

According to the method 1400, multiple fin heights on the same chip can offer an optimum solution for both high performance and low power circuits on the same chip without great degradation of performance.

Briefly, according to the present disclosure, either a portion of finFETs on a wafer or all of the finFETs on a wafer can be trimmed according to the desired power consumption by tuning the fin height of the corresponding fin(s). When all of the finFETs on a wafer are trimmed by the same magnitude, the finFETs of a semiconductor device are globally adjusted and no additional mask is required during the semiconductor manufacturing process. When a portion of finFETs on a wafer are trimmed into different fin heights, the finFETs of a semiconductor device are locally adjusted. Therefore, by applying the present disclosure, the power consumption of a semiconductor device can be optimized as per the requirement of the application.

In some embodiments of the present disclosure, a method for fabricating a semiconductor device on a wafer is disclosed. The method comprises: patterning a plurality of fins on the wafer; forming an STI region to surround the plurality of fins; and etching the STI region to form the plurality of fins having a fin height such that the semiconductor device has a desired power consumption. The plurality of fins corresponds to a plurality of finFETs of the semiconductor device respectively.

In some embodiments of the present disclosure, a method for fabricating a finFET on a wafer is disclosed. The method comprises: patterning a fin on the wafer; forming an STI region to surround the fin; and etching the STI region to form the fin with a fin height such that the finFET has a desired power consumption. The fin height is a length from a surface of the STI region to a top surface of the fin.

In some embodiments of the present disclosure, a method for adjusting a power consumption of a semiconductor device is disclosed. The method comprises: patterning a plurality of fins on the wafer; forming an STI region to surround the plurality of fins; and etching the STI region to form the plurality of fins to have a plurality of different fin heights for adjusting the power consumption of the semiconductor device. The plurality of fins corresponds to a plurality of finFETs of the semiconductor device respectively.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for fabricating a semiconductor device on a wafer, the method comprising:
patterning a plurality of fins on the wafer;
forming an STI (shallow-trench isolation) region to surround the plurality of fins; and
etching the STI region to form the plurality of fins having a fin height such that the semiconductor device has a desired power consumption, wherein the fin height is a length from a top surface of the STI region to a top surface of the plurality of fins, and the STI region surrounding the fin height of the plurality of fins is entirely etched;
wherein the plurality of fins corresponds to a plurality of finFETs of the semiconductor device, respectively.

2. The method of claim 1, wherein the desired power consumption of the semiconductor device is proportional to the fin height.

3. The method of claim 1, further comprising:
forming a plurality of gate stacks having a fixed gate length over the plurality of fins, respectively.

4. The method of claim 1, wherein when the fin height is greater than about 45 nm, the desired power consumption is a first power consumption; when the fin height is in a range of about 30˜45 nm, the desired power consumption is a second power consumption; and when the fin height is smaller than about 30 nm, the desired power consumption is a third power consumption, the first power consumption being higher than the second power consumption, and the second power consumption being higher than the third power consumption.

5. The method of claim 1, wherein patterning the plurality of fins on the wafer further comprises:
forming the plurality of fins to have a fin width;
wherein an effective width of each fin in the plurality of fins is a total length of the fin width and two times the fin height, and when the effective width of each fin in the plurality of fins is greater than about 95 nm, the desired power consumption is a first power consumption; when the effective width of each fin in the plurality of fins is in a range of about 75˜95 nm, the desired power consumption is a second power consumption; and when the effective width of each fin in the plurality of fins is smaller than about 75 nm, the desired power consumption is a third power consumption, the first power consumption being higher than the second power consumption, and the second power consumption being higher than the third power consumption.

6. The method of claim 1, wherein etching the STI region to form the plurality of fins having the fin height such that the semiconductor device has the desired power consumption comprises:
using a mask to mask an area other than the STI region on the wafer; and
etching the STI region to expose the plurality of fins having the fin height to make the semiconductor device have a specific power consumption.

7. A method for fabricating a finFET on a wafer, the method comprising:
patterning a fin on the wafer;
forming an STI (shallow-trench isolation) region to surround the fin; and
etching the STI region to form the fin with a fin height such that the finFET has a desired power consumption;
wherein the fin height is a length from a top surface of the STI region to a top surface of the fin, and the STI region surrounding the fin height of the fin is entirely etched.

8. The method of claim 7, wherein the desired power consumption of the finFET is proportional to the fin height.

9. The method of claim 7, further comprising:
forming a gate stack having a fixed gate length over the fin.

10. The method of claim 7, wherein when the fin height of the fin is greater than about 45 nm, the desired power consumption is a first power consumption; when the fin height of the fin is in a range of about 30˜45 nm, the desired power consumption is a second power consumption; and when the fin height of the fin is smaller than about 30 nm, the desired power consumption is a third power consumption, the first power consumption being higher than the second power consumption, and the second power consumption being higher than the third power consumption.

11. The method of claim 7, wherein patterning the fin on the wafer further comprises:
forming the fin to have a fin width;
wherein an effective width of the fin is a total length of the fin width and two times the fin height; and when the effective width of the fin is greater than about 95 nm, the desired power consumption is a first power consumption; when the effective width of the fin is in a range of about 75˜95 nm, the desired power consumption is a second power consumption; and when the effective width of the fin is smaller than about 75 nm, the desired power consumption is a third power consumption, the first power consumption being higher than the second power consumption, and the second power consumption being higher than the third power consumption.

12. The method of claim 7, wherein etching the STI region to form the fin having the fin height such that the finFET has the desired power consumption comprises:
using a mask to mask an area other than the STI region on the wafer; and
etching the STI region to expose the fin having the fin height to make the finFET have the desired power consumption.

13. A method for adjusting a power consumption of a semiconductor device, the method comprising:
patterning a plurality of fins on the wafer;
forming an STI (Shallow-trench isolation) region to surround the plurality of fins; and
etching the STI region to form the plurality of fins having a plurality of different fin heights for adjusting the power consumption of the semiconductor device;
wherein the plurality of fins corresponds to a plurality of finFETs of the semiconductor device, respectively, and wherein, for each fin in the plurality of fins, the fin height is a length from a top surface of the STI region to a top surface of the fin, and the STI region surrounding the fin height of the fin is entirely etched.

14. The method of claim 13, further comprising:
forming a plurality of gate stacks having a fixed gate length over the plurality of fins, respectively.

15. The method of claim 13, wherein a first fin height is greater than about 45 nm, a second fin height is in a range of about 30˜45 nm, and a third fin height is smaller than about 30 nm.

16. The method of claim 13, wherein etching the STI region to form the plurality of fins having the plurality of different fin heights for adjusting the power consumption of the semiconductor device comprises:
for a first fin in the plurality of fins:
etching the STI region to form the first fin having a first fin height such that a first finFET corresponding to the first fin has a first power consumption;
for a second fin in the plurality of fins:
etching the STI region to form the second fin having a second fin height such that a second finFET corresponding to the second fin has a second power consumption;
wherein the first fin height is greater than the second fin height, and the first power consumption is larger than the second power consumption.

17. The method of claim 16, wherein etching the STI region to form the plurality of fins having the plurality of different fin heights for adjusting the power consumption of the semiconductor device further comprises:
for a third fin in the plurality of fins:
etching the STI region to form the third fin having a third fin height such that a third finFET corresponding to the third fin has a third power consumption;
wherein the second power consumption is larger than the third power consumption.

18. The method of claim 13, wherein patterning the plurality of fins on the wafer further comprises:
forming the plurality of fins having a fin width, and an effective width of a fin in the plurality of fins is a total length of the fin width and two times a corresponding fin height;
for a first fin in the plurality of fins:
etching the STI region to form the first fin having a first effective width such that a first finFET corresponding to the first fin has a first power consumption; and
for a second fin in the plurality of fins:
etching the STI region to form the second fin having a second effective width such that a second finFET corresponding to the second fin has a second power consumption;
wherein the first effective width is greater than the second effective width, and the first power consumption is larger than the second power consumption.

19. The method of claim 18, further comprising:
for a third fin in the plurality of fins:
etching the STI region to form the third fin having a third effective width such that a third finFET corresponding to the third fin has a third power consumption;
wherein the second power consumption is larger than the third power consumption.

20. The method of claim 19, wherein the first effective width is greater than about 95 nm, the second effective width is in a range of about 75˜95 nm, and the third effective width is smaller than about 75 nm.
